(19) United States
(12) Patent Application Publication
(10) Pub. No.: US 2025/0240953 A1
(43) Pub. Date: Jul. 24, 2025

(54) METHOD FOR MANUFACTURING AN INTEGRATED CIRCUIT, AND CORRESPONDING INTEGRATED CIRCUIT

(71) Applicant: STMicroelectronics International N.V., Geneva (CH)

(72) Inventors: Abderrezak MARZAKI, Cabries (FR); Carlos Augusto SUAREZ SEGOVIA, Seyssinet-Pariset (FR)

(73) Assignee: STMicroelectronics International N.V., Geneva (CH)

(21) Appl. No.: 19/024,438

(22) Filed: Jan. 16, 2025

(30) Foreign Application Priority Data
Jan. 19, 2024 (FR) FR2400559

(51) Int. Cl. H10B 41/35; H01L 21/762; H10B 41/10; H10D 30/01; H10D 30/68

(52) U.S. Cl. CPC H10B 41/35; H01L 21/76224; H10D 30/0411; H10D 30/6892; H10B 41/10

(57) ABSTRACT

An integrated circuit includes lateral isolation regions delimiting active regions in a semiconductor substrate. A trench is etched extending vertically in depth into the semiconductor substrate and intended to pass through the lateral isolation regions and the active regions. The formation of the lateral isolation regions includes forming sacrificial lateral isolation regions positioned at a location of the etching of the trench which passes through the active regions.

### PRIORITY CLAIM

This application claims the priority benefit of French Application for Patent No. 2400559, filed on Jan. 19, 2024, the content of which is hereby incorporated by reference in its entirety to the maximum extent allowable by law.

### TECHNICAL FIELD

Implementations and embodiments relate to integrated circuits and, in particular, to integrated circuits which include a trench extending vertically in depth in the substrate, such as integrated circuits incorporating a vertical-gate buried transistor, for example transistors for access to non-volatile memory cells.

### BACKGROUND

FIGS. 1A, 1B and 1C illustrate an example of a memory plane incorporating memory cells CEL1, CEL2 in a non-volatile memory technology which includes each of the memory cells CEL1, CEL2 being provided with a floating-gate state transistor TE in series with a vertical-gate buried access transistor TA.

FIG. 1A illustrates the arrangement of the memory cells in a top view of the memory plane (in the semiconductor part, usually designated or referred to in the art as Front End Of Line (FEOL).

FIG. 1B illustrates a cross-section view in the plane BB of FIG. 1A, the plane BB passing through gate regions of the state transistors and the vertical gate region in width.

FIG. 1C illustrates a cross-section view in the plane CC of FIG. 1A, passing through the vertical gate region in length.

Briefly, the state transistor TE makes it possible to store a charge representative of a binary data item in its floating gate FG, and the access transistor TA makes it possible to selectively access the memory cell CEL1, CEL2 in write and read mode for example.

In addition, to access the memory cells CEL1, CEL2, the drain region D of the state transistor TE is typically connected to a bit line BL1, BL2, while the source region of the access transistor TA is accessed by a region NISO implanted in depth into the substrate, which can be referred to as the source plane.

Typically, the bottom of the vertical gate TRG of the access transistor TA does not contact the source plane NISO in depth, and a source region Simp (also called source implant) is implanted into the substrate from the bottom of a trench that has been etched to form the vertical gate TRG therein, between the bottom of the vertical gate TRG and the source plane NISO. The source implant Simp is thus provided to ensure electrical continuity of the source region of the vertical gate transistor TRG with the source plane NISO.

It has been noticed by the inventors that a performance limitation and yield loss in this non-volatile memory technology could be related to a low access current in the memory cell, caused by a high resistance between the source-drain conduction regions of the access transistor TA in the on-state.

This is because, if the trench including the vertical gate TRG has an effective depth p11 which is less than a nominal depth p10, then it is possible that the electrical continuity between the source implant Simp and the source plane NISO may be poorly established, which causes said increase in the resistance of the access transistor TA.

The inventors have furthermore established a correlation between the increase in the resistance of the access transistor TA and the depth of lateral isolation regions STI, typically shallow isolation trenches.

In fact, the trench containing the vertical gate TRG is etched, especially through lateral insulation regions STI at the surface of the substrate, typically of silicon oxide, and then into the substrate, typically of single crystal silicon. However, etching the trench is much more rapid in silicon oxide than in the single crystal substrate.

Consequently, for an equal etch time, the depth p11 of the trench TRG will be smaller if the depth p21 of the lateral isolation region STI is smaller, and the depth p10 of the trench TRG will be larger (or at a nominal value) if the depth p20 of the lateral isolation region STI is larger (or at a nominal value).

Finally, a reduction in the depth p21 of the lateral insulation regions STI in practice, compared with the nominal depth p20 provided for in the design, may be caused by a phenomenon of stopping etching of the shallow insulation trenches STI, usually called “STI etch stop”.

This undesirable phenomenon is basically caused by saturation of the etched material (reagent) or the products of the etching reaction in an etched space that is too narrow. Thus the “STI etch stop” phenomenon is linked to the narrow width of the lateral isolation regions STI. On the other hand, for a constant width in the design of the lateral isolation regions STI, this phenomenon can occur with random variations in the manufacturing methods, especially with regard to the position on the semiconductor wafer, and is difficult to control.

There accordingly exists a need in the art to address the foregoing concerns.

### SUMMARY

Embodiments and implementations of the aspects set out hereinafter suggest forming a sacrificial lateral isolation region facing the entire location of the trench etch, on the one hand in order to prevent the “STI etch stop” phenomenon and on the other hand in order to obtain vertical gate structures whose bottom is located deeper, and furthermore at a depth showing substantially no variation along the entire length of the trench. In particular, the bottom of the trench is at an equal depth to the locations in the trench that pass through the lateral isolation regions and the locations that pass through the active regions.

It will be noted in particular that the solutions provided in the embodiments and implementations defined hereinafter advantageously do not involve modifying the chemical reaction involved in the etching of shallow isolation STI trenches, which would be costly and difficult to put into practice in existing methods; nor to modify overall the nominal width of the lateral isolation regions, which would affect overall the performance of the active regions and/or the total surface area of the circuit; nor to increase the trench etching time, which would also have an impact on other device formations using the same step of etching the vertical gate buried transistor.

Thus, according to one aspect, a method for manufacturing an integrated circuit is provided, comprising: forming lateral isolation regions delimiting active regions in a semiconductor substrate, and etching a trench extending vertically in depth into the substrate and intended to pass through said lateral isolation regions and said active regions, wherein said forming lateral isolation regions comprises forming sacrificial lateral isolation regions positioned at the location passing through the active regions of said etching the trench.

By “the location passing through the active regions”, it is meant the location where the active regions are situated on either side of the trench.

Furthermore, although they are of the same nature and formed in the same step, a distinction is made between lateral insulation regions whose function is to delimit active regions of the circuit obtained after manufacture, and sacrificial lateral insulation regions whose function is to be etched (sacrificed) to improve implementation of the etching step.

In fact, on the one hand, the extent of the lateral isolation regions, with respect to the location of etching, does not have the narrow width that causes the “STI etch stop” phenomenon. This, therefore, prevents the reduction in the depth of vertical gate trenches relating to the reduction in the depth of shallow isolation regions, and thus especially prevents the loss of performance caused by high resistance between the source-drain conduction regions of the access transistor in the on-state.

And on the other hand, the trenches etched through the sacrificial lateral isolation regions are deeper than trenches conventionally etched into the semiconductor substrate, again contributing to increasing the depth of the bottom of the trench, especially in order to prevent loss of performance caused by high resistance between the source-drain conduction regions of the access transistor in the on-state.

According to an implementation mode, the formation of sacrificial lateral insulation regions is positioned so as to be completely removed during said etching the trench, so that the flanks of the etched trench include an uncovered wall of said active regions.

Thus, the presence of sacrificial lateral isolation regions has no effect on the interface (the uncovered wall) between the active regions and the trench after etching.

According to one mode of implementation, said forming lateral insulation regions delimits the active regions in strips extending lengthwise in a first direction, while said trench extends lengthwise in a second direction perpendicular to the first direction, the sacrificial lateral insulation regions being positioned along the length of the trench in the second direction.

Thus, the sacrificial side isolation regions are positioned so as to “pass through” the active regions in the second direction, and trench etching is done at a location facing the sacrificial side regions only, and not facing an alternation of strips of active regions and lateral isolation regions.

According to one implementation mode, the lateral isolation regions are formed by a volume of dielectric material in the substrate, while the active regions are formed by the semiconductor material of the substrate; the dynamics of trench etching being faster in the dielectric material than in the semiconductor material of the substrate.

According to one embodiment, a gate of a vertical-gate buried access transistor is formed in said trench etched in depth in the substrate, and a stack of a floating gate and of a control gate of a state transistor at least partly covering said active regions in the vicinity of the trench is formed.

According to another aspect, an integrated circuit is also provided comprising lateral isolation regions delimiting active regions in a semiconductor substrate, and a device arranged in a trench extending vertically deep into the substrate and through said lateral isolation regions and said active regions, wherein the bottom of the trench is located at a constant and equal depth facing the locations of the trench which pass through the lateral isolation regions and the locations which pass through the active regions.

According to one embodiment, the component arranged in the trench includes flanks directly in contact with the active regions, at locations in the trench that pass through the active regions.

According to one embodiment, the lateral isolation regions delimit the active regions in strips extending lengthwise in a first direction, while the said trench extends lengthwise in a second direction perpendicular to the first direction, the bottom of the trench being located at a constant and equal depth along the second direction.

According to one embodiment, the integrated circuit includes a vertical-gate buried access transistor, the vertical gate being the component arranged in said trench, and a state transistor including a stack of a floating gate and of a control gate at least partly covering said active regions in the vicinity of the trench.

According to another aspect, a semiconductor device is also provided, comprising lateral isolation regions delimiting active regions in a semiconductor substrate, wherein sacrificial lateral isolation regions are further positioned through the active regions; the semiconductor device being able to be shaped by etching a trench at the location of the sacrificial lateral isolation regions, by a method as defined hereinbefore.

This aspect of a semiconductor device corresponds in particular to an integrated circuit “intermediate device” obtained during the manufacturing method defined hereinbefore, especially before the step of etching a trench extending vertically deep into the substrate and intended to pass through said lateral isolation regions and said active regions.

### BRIEF DESCRIPTION OF THE DRAWINGS

Other advantages and characteristics of the invention will become apparent upon examining the detailed description of embodiments and implementations in no way limiting, and from the accompanying drawings, wherein:

FIGS. 1A, 1B and 1C illustrate an example of a memory plane incorporating memory cells in a non-volatile memory technology;

FIGS. 2A, 2B and 2C illustrate the result of a step of a method for manufacturing an integrated circuit where lateral isolation regions and sacrificial lateral isolation regions are formed in a semiconductor substrate;

FIGS. 3A, 3B and 3C illustrate the memory plane at the end of the step of etching a trench extending in depth into the substrate;

FIGS. 4A, 4B and 4C illustrate the memory plane at the end of forming a gate structure in the trench; and

FIGS. 5A, 5B and 5C illustrate the memory plane at the end of the steps completing forming memory cells and, in particular, forming state transistors.

### DETAILED DESCRIPTION

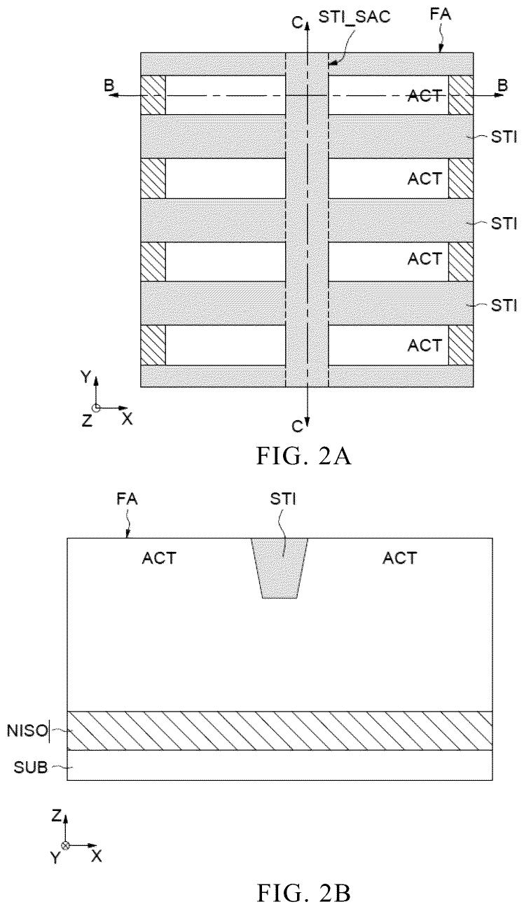

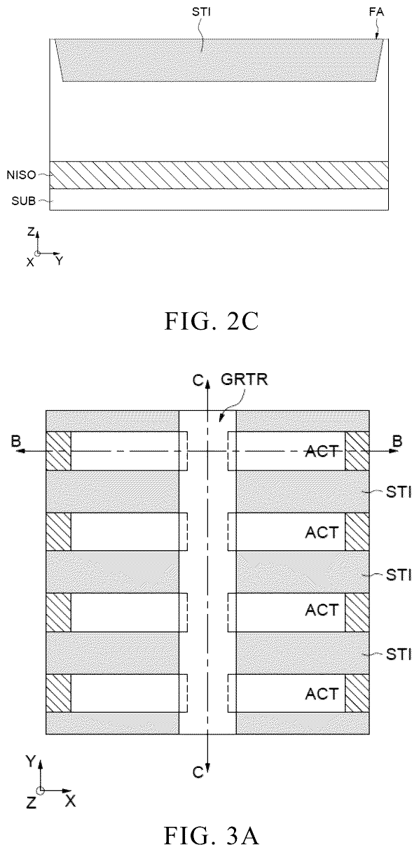

FIGS. 2A, 2B and 2C illustrate the result of a step of forming lateral isolation regions STI and sacrificial lateral isolation regions STI_SAC, in a semiconductor substrate SUB of a method for manufacturing an integrated circuit, more particularly in a memory plane of the integrated circuit, intended to include memory cells.

In the following, for convenience, the terms “lateral isolation regions STI, STI_SAC” will refer to the assembly including the lateral isolation regions STI and the sacrificial lateral isolation regions STI_SAC.

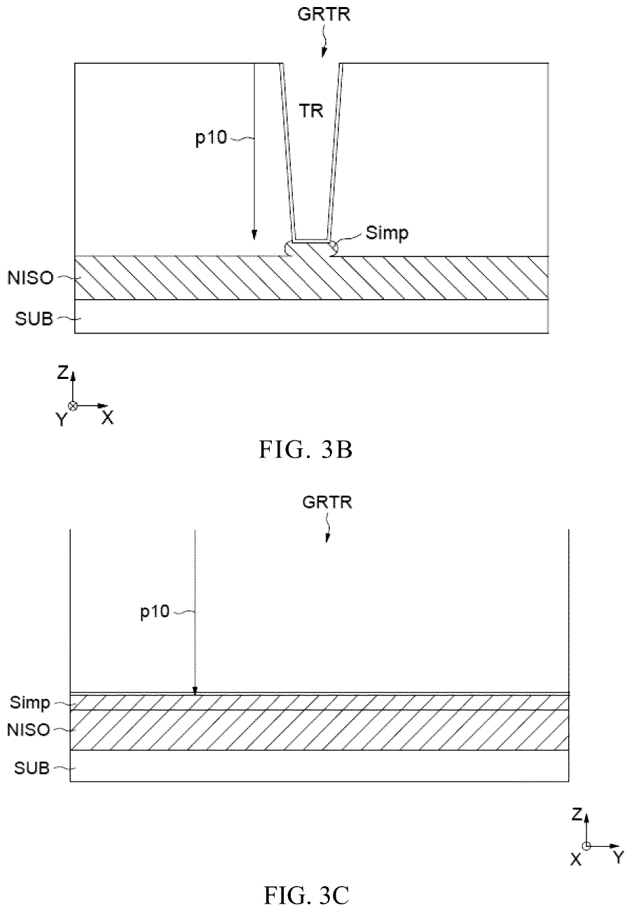

An orthogonal reference frame XYZ common to FIGS. 2A-2B-2C, as well as FIGS. 3A-3B-3C, 4A-4B-4C, 5A-5B-5C, described hereinafter, is defined.

The first direction X and the second direction Y lie in the plane of the front face FA (see hereinbefore), and the third direction Z is vertical, i.e., perpendicular to the plane of the front face FA.

FIG. 2A illustrates a top view of the front face FA of the substrate SUB (see hereinafter).

FIG. 2B illustrates a cross-section view in the plane BB of FIG. 2A. The plane BB directed by the first direction X and the vertical direction Z is positioned in the length of the active region ACT (see below).

FIG. 2C illustrates a cross-section view in the plane CC of FIG. 2A. The plane CC is directed by the second direction Y and the vertical direction Z, and is positioned through the sacrificial lateral isolation region STI_SAC.

The front face FA of the substrate SUB is the face from which the devices of the semiconductor part are made, usually designated “FEOL”, for “Front End Of Line”.

Before or after forming the lateral isolation regions STI, STI_SAC, a region NISO implanted deep into the semiconductor substrate SUB has been formed. The deep implanted region NISO, with a dopant type opposite to the type of dopants of the substrate SUB, may offer the function of memory-cell source plane. Conventionally, virtually no further steps are carried out prior to forming the lateral isolation regions STI, STI_SAC.

The lateral isolation regions STI, STI_SAC are formed in a surface region of the semiconductor substrate SUB from the front face FA, i.e., a shallow region, for example of substantially 300 nm or between 200 nm and 400 nm.

The lateral isolation regions STI, STI_SAC are obtained by a shallow isolation trench technique, i.e., they are obtained by etching shallow trenches (for example 300 nm to 400 nm) open into the surface region of the substrate SUB, and filling the trenches with a dielectric material, typically silicon oxide.

The lateral isolation regions STI delimit active regions ACT of the substrate, which extend in strips whose length is directed by the first direction X.

Among the lateral isolation regions formed in this step, sacrificial lateral isolation regions STI_SAC are positioned at the location of the future etching of the trench TR (FIGS. 3A-3B-3C), especially the location passing through the active regions ACT, perpendicularly in the second direction Y.

Thus, in absolute terms, the active regions ACT are in the form of strips extending in the first direction X, interrupted by the sacrificial lateral insulation regions STI_SAC which pass through them laterally in the second direction Y.

FIGS. 3A, 3B and 3C illustrate the memory plane at the end of the step of etching GRTR a trench extending deep into the substrate SUB.

FIG. 3A illustrates a top view of the front face FA of the substrate SUB.

FIG. 3B illustrates a cross-section view in the plane BB of FIG. 3A (identical to the plane BB of FIG. 2A).

FIG. 3C illustrates a cross-section view in the plane CC of FIG. 3A (identical to the plane CC of FIG. 2A).

The etch GRTR is positioned in place of the sacrificial lateral isolation region STI_SAC, and may especially be provided wider in the second direction Y so as to satisfy a margin of error in the alignment of the masks of the respective etches. Note that the mask of the trench etch GRTR can be directly aligned with the mask of the lateral isolation trench etch STI, STI_ACT. Thus, the margin of error to be satisfied is advantageously minimal (as it does not have to take account of an accumulation of margins of error from a succession of alignments between the two etching steps).

The trench TR thus etched extends lengthwise in the second direction Y and passes laterally through a succession of strips of lateral isolation regions STI and active regions ACT, extending lengthwise in the first direction X.

The technique of etching GRTR the trench TR is typically a dry etching of the reactive ion type, usually Reactive Ion Etching (RIE). This etching type conventionally exhibits faster dynamics in the dielectric material of the lateral isolation regions STI, typically silicon oxide, than in the semiconductor material of the active regions ACT, typically of single crystal silicon.

Consequently, at the moment when the etch GRTR reaches the bottom of the shallow isolation trenches STI, the parts facing the position of the shallow isolation regions STI are more deeply etched than the parts facing the position of the active regions ACT.

However, because the sacrificial lateral isolation regions STI_SAC are positioned at the location of this etch GRTR, only parts facing the position of the shallow isolation regions STI are etched (to the greatest depth), with uniform etching dynamics along the entire length (second direction Y) of the trench TR.

Thus, the bottom of the trench TR has a shape with substantially no variation in depth along the second direction Y. In other words, the bottom of the trench TR is thus located at a constant depth p10, in particular with respect to the locations of the trench which pass through the lateral isolation regions STI and the locations which pass through the active regions ACT. In other words the bottom of the trench is located at equal depths in relation to the locations of the trench TR that pass through the lateral isolation regions STI, and in relation to the locations of the trench TR that pass through the active regions ACT, in the top view of FIG. 3A.

Indeed, by “constant depth” or “equal depths” it is meant that the depths do not vary substantially, i.e., the variations are less than or equal to a variation threshold for the etching method.

Moreover, a source region Simp, also referred to as source implant Simp, is implanted in the substrate SUB, from the bottom of the trench TR, between the bottom of the trench TR and the source plane NISO. The source implant Simp is designed to ensure electrical continuity with the source plane NISO.

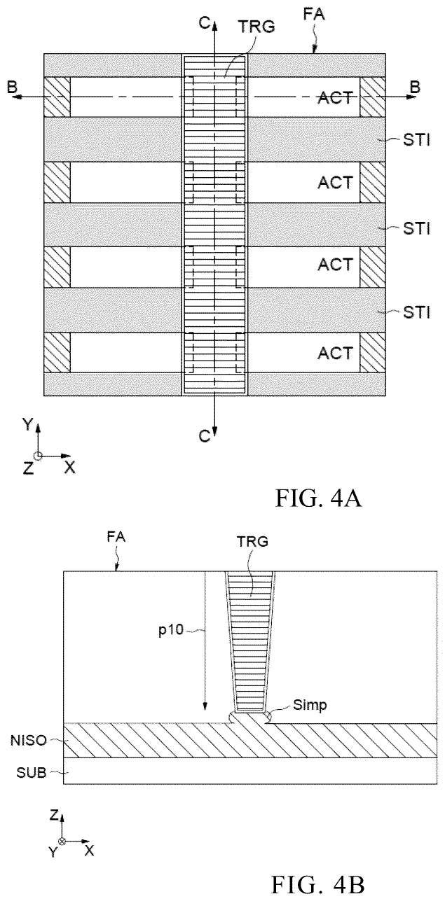

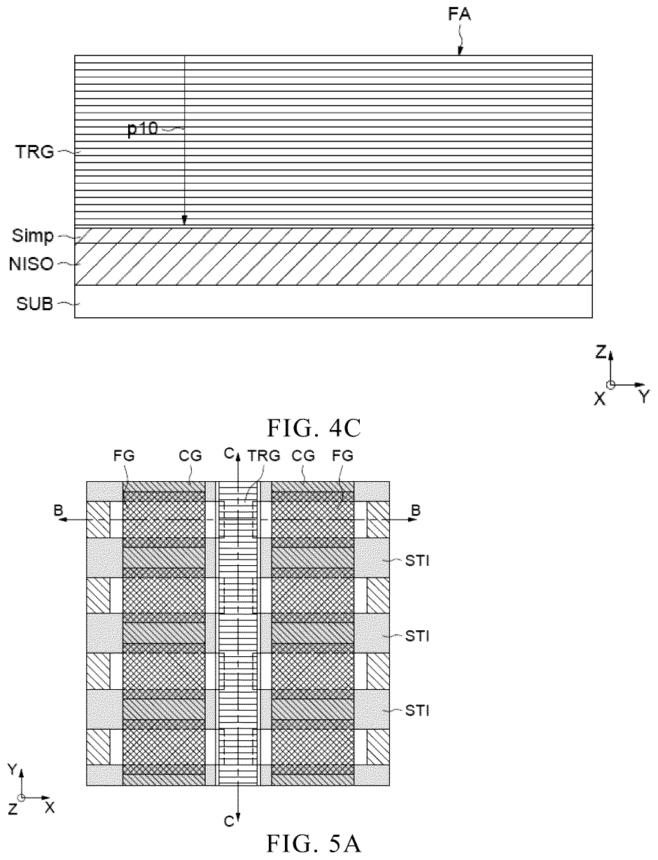

FIGS. 4A, 4B and 4C illustrate the memory plane at the end of forming a gate structure TRG in the trench TR extending deep into the substrate SUB.

FIG. 4A illustrates a top view of the front face FA of the substrate SUB.

FIG. 4B illustrates a cross-section view in the plane BB of FIG. 4A (identical to the plane BB of FIGS. 2A and 3A).

FIG. 4C illustrates a cross-section view in the plane CC of FIG. 4A (identical to the plane CC of FIGS. 2A, 3A).

Firstly, a dielectric gate layer has been formed on the bottom and flanks of the trench TR thus opened into the semiconductor substrate SUB, typically by oxidation.

Secondly, a conductive gate region has been formed in the volume of the trench, typically by depositing excess polycrystalline silicon overflowing over the front face FA, and a chemical-mechanical polishing step up to the front face FA.

The gate structure TRG thus arranged in the trench TR includes the dielectric gate envelope on the flanks and bottom of the trench, and the conductive gate region in the volume delimited by the envelope and the front face FA.

A source region Simp, NISO, and the vertical gate structure TRG, of a buried access transistor TA, for memory cells of the memory plane, have thus been formed in the trench TR.

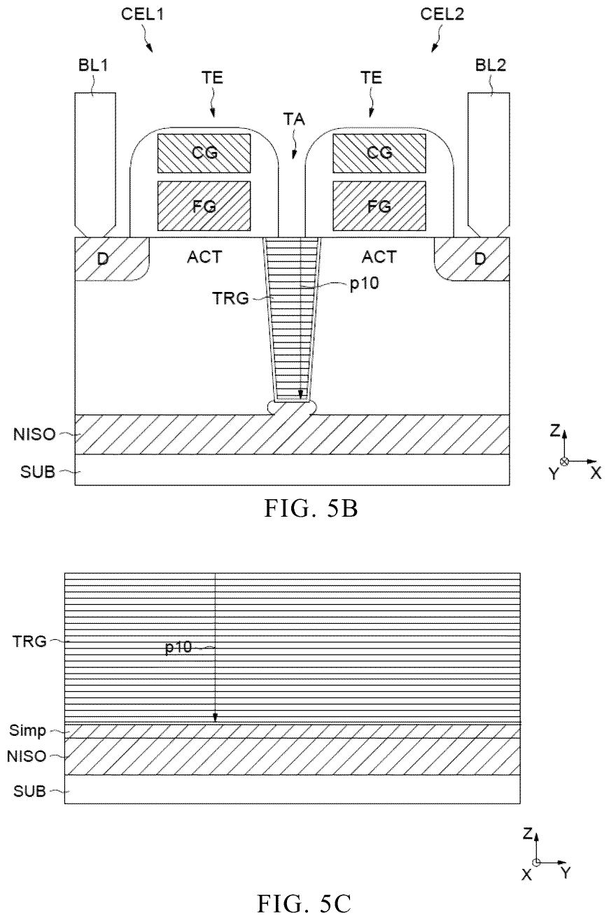

FIGS. 5A, 5B and 5C illustrate the memory plane at the end of the steps completing forming memory cells CEL1, CEL2, in particular forming state transistors TE.

FIG. 5A illustrates a top view of the front face FA of the substrate SUB.

FIG. 5B illustrates a cross-section view in the plane BB of FIG. 5A. The plane BB is identical to the plane BB of FIGS. 2A, 3A, 4A and passes through the gate regions CG, FG of the state transistors TE lengthwise and the vertical gate region TRG widthwise.

FIG. 5C illustrates a cross-section view in the plane CC of FIG. 5A. The plane CC is identical to the plane CC in FIGS. 2A, 3A and 4A and passes through the vertical gate region lengthwise.

The steps completing forming the memory cells CEL1, CEL2 comprise forming state transistors TE including a floating gate FG with a control gate CG thereabove.

The conduction regions of the state transistor TE are implanted in the active regions ACT. The drain region D is connected to a respective bit line BL1, BL2, while the source region (not represented) of the state transistor TE is also the drain region of the access transistor TA, and makes series connection between the state transistor TE and the access transistor TA.

The bit lines BL1, BL2 are for example formed in a metal level extending above the memory plane in the first direction X.

The control gates CG can be made so as to extend in the second direction Y, being able to form control gate lines used for selectively accessing the memory cells, belonging to one and the same group called a row.

The access transistor TA is also made so as to extend in the second direction Y, and can form a word line used for selectively accessing the memory cells, belonging to one and the same group called a memory word.

The floating gates FG are formed so as to cover the active regions ACT specific to each memory cell CEL1, CEL2, on either side, in the first direction X, of the vertical gate TRG.

In particular, the interface between each floating gate FG and the underlying active region ACT is designed to implement charge injections by “tunnel effect” through a tunnel oxide layer, typically by Fowler-Nordheim effect, and/or by injecting hot carriers resulting from impact ionizations.

The reliability and cycling performance of the memory cells CEL1, CEL2 are especially determined by the width of the tunnel effect injection interface, i.e., the width of the active regions ACT, i.e., the width of the active regions ACT in the second direction Y. The greater the width of the active regions ACT, the greater the reliability of the memory cells.

Thus, by virtue of the sacrificial lateral isolation regions, it will have been possible to guard against the phenomenon of etching stop of the lateral isolation regions “STI etch stop” facing the trench TRG, caused by the narrow width of the lateral isolation regions (in the second direction Y), without at the same time widening the lateral isolation regions STI (in the second direction Y), and thus without consequently reducing the width of the active regions ACT or the relative reliability y of the memory cells CEL1, CEL2.

Avoiding the problem of etching stop of the lateral isolation regions “STI etch stop” consequently avoids the risk of loss of read and write performance, by avoiding the reduction in the depth of the vertical gate trenches which can generate high resistance between the source-drain conduction regions of the access transistor TA in the on-state.

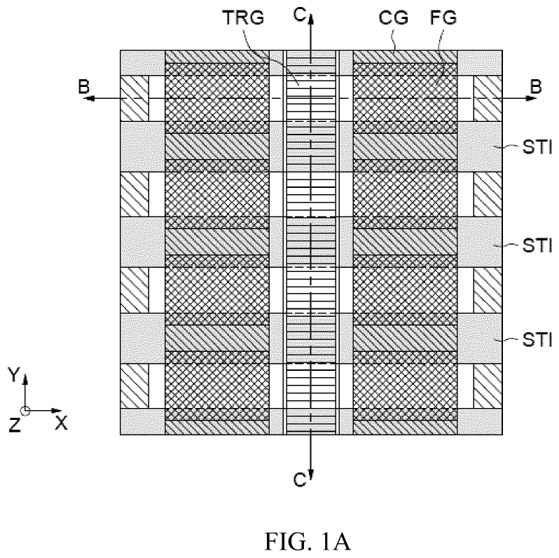

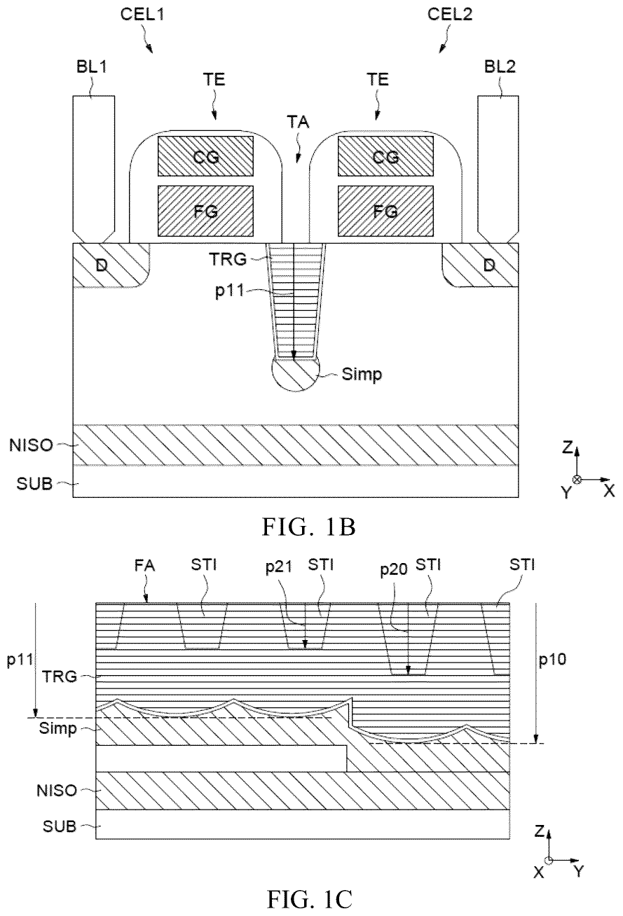

And on the other hand, the design of the sacrificial lateral isolation region STI_SAC further enables the trenches TR accommodating the vertical gate TRG to be formed with a depth p10 greater than the depth p11 (FIGS. 1A, 1B, 1C) of a trench etched with the same step in the semiconductor substrate SUB. This additional effect also helps to prevent the risk of loss of read and write performance of memory cells.

Furthermore, from the point of view of the final device obtained by the method described previously in connection with FIGS. 2A-C to 5A-C, the bottom of the trench TR containing the vertical gate TRG, has a very uniform and flat appearance, and is especially located at a constant and equal depth p10 with respect to the locations of the trench which pass through the lateral isolation regions STI and which pass through the active regions ACT.

These advantages are in particular consequences resulting from the structure of the “intermediate” semiconductor device, obtained in the course of the method at the end of the step of forming lateral isolation regions STI, STI_SAC, as illustrated by FIGS. 2A, 2B, 2C; i.e., a semiconductor device comprising lateral isolation regions STI delimiting active regions ACT in a semiconductor substrate SUB, in which sacrificial lateral isolation regions STI_SAC are further positioned through the active regions ACT, the semiconductor device being able, or even intended, to be shaped by etching a trench GRTR at the location of the sacrificial lateral isolation regions STI_SAC as hereinbefore described in connection with FIGS. 3A-3B-3C, 4A-4B-4C, and 5A-5B-5C.

1. A method for manufacturing an integrated circuit, comprising:
forming lateral isolation regions delimiting active regions in a semiconductor substrate; and
etching a trench extending vertically in depth into the semiconductor substrate to pass through said lateral isolation regions and said active regions;
wherein forming lateral isolation regions comprises forming sacrificial lateral isolation regions positioned at a location of said etching the trench to pass through the active regions.

2. The method according to claim 1, wherein forming sacrificial lateral isolation regions comprises positioning the sacrificial lateral isolation regions to be completely removed during said etching the trench, so that the flanks of the etched trench include an uncovered wall of said active regions.

3. The method according to claim 1, wherein forming lateral isolation regions delimits the active regions in strips extending lengthwise in a first direction, and wherein etching the trench forms said trench to extend lengthwise in a second direction perpendicular to the first direction, and wherein the sacrificial lateral isolation regions are positioned along a length of the trench in the second direction.

4. The method according to claim 1, wherein the lateral isolation regions comprise a volume of dielectric material in the semiconductor substrate, wherein the active regions comprise semiconductor material of the semiconductor substrate, and wherein etching the trench comprises etching faster in the dielectric material than in the semiconductor material of the semiconductor substrate.

5. The method according to claim 1, further comprising forming a gate of a buried access transistor with vertical gate in said trench etched in depth into the semiconductor substrate, and forming a stack of a floating gate and of a control gate of a state transistor at least partly covering said active regions in a vicinity of where the trench is formed.

6. A semiconductor device, comprising:
lateral isolation regions delimiting active regions in a semiconductor substrate; and
sacrificial lateral isolation regions positioned through the active regions;
wherein a trench at the location of the sacrificial lateral isolation regions shapes the semiconductor device, said trench extending vertically in depth into the semiconductor substrate to pass through said lateral isolation regions and said active regions.

7. The semiconductor device of claim 6, wherein the lateral isolation regions delimit the active regions in strips extending lengthwise in a first direction, and wherein said trench extends lengthwise in a second direction perpendicular to the first direction, and wherein the sacrificial lateral isolation regions are positioned along a length of the trench in the second direction.

8. The semiconductor device of claim 6, wherein the lateral isolation regions comprise a volume of dielectric material in the semiconductor substrate, wherein the active regions comprise semiconductor material of the semiconductor substrate.

9. The semiconductor device of claim 6, further comprising a gate of a buried access transistor with vertical gate in said trench etched in depth into the semiconductor substrate, and a stack of a floating gate and of a control gate of a state transistor at least partly covering said active regions in a vicinity of the trench.

10. An integrated circuit, comprising:
lateral isolation regions delimiting active regions in a semiconductor substrate; and
a component arranged in a trench extending vertically in depth into the semiconductor substrate and through said lateral isolation regions and said active regions;
wherein a bottom of the trench is located at a constant and equal depth facing locations of the trench which pass through the lateral isolation regions and locations of the trench which pass through the active regions.

11. The integrated circuit according to claim 10, wherein the component arranged in the trench includes flanks directly in contact with the active regions, at the locations in the trench which pass through the active regions.

12. The integrated circuit according to claim 10, wherein the lateral isolation regions delimit the active regions in strips extending lengthwise in a first direction, wherein said trench extends lengthwise in a second direction perpendicular to the first direction, and wherein the bottom of the trench is located at a constant and equal depth along the second direction.

13. The integrated circuit according to claim 10, further including:
a buried access transistor with a vertical gate, the vertical gate being the component arranged in said trench; and
a state transistor including a stack of a floating gate and a control gate covering at least part of said active regions in a vicinity of the trench.
